(19) United States
(12) Patent Application Publication
(10) Pub. No.: US 2026/0130057 A1
(43) Pub. Date: May 7, 2026

(54) DISPLAY PANEL, PREPARATION METHOD THEREFOR, AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Peng QIN, Kunshan (CN); Yang YANG, Hefei (CN); Jinfang ZHANG, Hefei (CN)

(73) Assignees: Hefei Visionox Technology Co., Ltd., Hefei (CN); Visionox Technology Inc., Kunshan (CN)

(21) Appl. No.: 19/333,280

(22) Filed: Sep. 18, 2025

(30) Foreign Application Priority Data
Nov. 7, 2024 (CN) 202411590874.7

(51) Int. Cl. H10K 59/122; H10K 59/12; H10K 59/80; H10K 102/00; H10K 102/10

(52) U.S. Cl. CPC H10K 59/122; H10K 59/1201; H10K 59/80517; H10K 2102/103; H10K 2102/351

(57) ABSTRACT

The present application provides a display panel, preparation method thereof, and display device. The display panel includes a substrate; an insulating layer disposed on the substrate, with a plurality of first electrodes spaced apart from each other on a side of the insulating layer away from the substrate; a pixel defining layer disposed on the side of the insulating layer away from the substrate and having a plurality of pixel openings, wherein the pixel openings expose portions of the first electrodes and cover edges of the first electrodes, and gaps exist between the edges of the first electrodes and the insulating layer, improving inorganic cracks at the boundaries of the first electrodes and enhancing the encapsulation effect of the display area.

### CROSS-REFERENCE TO RELATED APPLICATIONS

The present application claims priority to Chinese Patent Application No. 202411590874.7, filed on Nov. 7, 2024 and entitled “DISPLAY PANEL, PREPARATION METHOD THEREFOR, AND DISPLAY DEVICE”, which is incorporated herein by reference in its entirety.

### FIELD

The present application relates to the field of display technology, in particular to a display panel, preparation method thereof, and display device.

### BACKGROUND

The development of semiconductor technology plays a crucial role in the advancement of electronic industry. Organic Light-Emitting Diode (OLED) has attracted significant attention and has been widely applied in electronic display products due to its advantages such as simple preparation process, low cost, low power consumption, high brightness, wide viewing angle, high contrast ratio, and capability for flexible display.

However, the process performance of current OLED display products needs improvement.

### SUMMARY

The present application provides a display panel, preparation method thereof, and display device, aiming to improve the process performance of the display panel.

A display panel includes a substrate; an insulating layer disposed on the substrate, and a plurality of first electrodes are spaced apart from each other on a side of the insulating layer away from the substrate; a pixel defining layer disposed on the side of the insulating layer away from the substrate and having a plurality of pixel openings, and an orthogonal projection of a pixel opening on the substrate in a thickness direction of the substrate overlaps with a portion of the first electrode and covers an edge of the first electrode, and a gap exists between the edge of the first electrode and the insulating layer.

An embodiment of the present application provides a method for preparing a display panel, including:
forming an insulating layer on a substrate;
forming a first conductive layer on the insulating layer and patterning the first conductive layer to form a first electrode;
forming a pixel defining layer having a plurality of pixel openings through a patterning process on the insulating layer where the first electrode is formed, and the pixel defining layer continuously covers the insulating layer, a side surface of the first electrode, and a portion of a surface of the first electrode away from the insulating layer.

An embodiment of the present application provides a display device, including the above-mentioned display panel, or including the display panel prepared by the above-mentioned preparation method.

Compared with the prior art, by changing the deposition rate of the pixel defining layer during preparation to achieve rapid sealing at the undercut of the first electrode, to retain a portion of gap under the first electrode (where no material is filled), the present application improves the boundary condition and crack issues at the edge of the first electrode.

### BRIEF DESCRIPTION OF THE DRAWINGS

In order to more clearly illustrate the embodiments of the present application or the prior art, a brief description of the accompanying drawings required for describing the embodiments or the prior art is provided below. The accompanying drawings in the following description show merely some embodiments of the present application, and other drawings may be derived from these accompanying drawings.

FIG. 1 is a structural diagram of a display panel according to an embodiment of the present application;

FIG. 2 is a sectional view of a light-emitting device with the light-emitting functional layer and encapsulation layer removed at position a in FIG. 1;

FIG. 3 is an enlarged view of position b in FIG. 2;

FIG. 4 is a sectional view of a modified isolation structure of the embodiment in FIG. 2;

FIG. 5 is a sectional view of a modified light-emitting device of the embodiment in FIG. 2;

FIG. 6 is an enlarged view of position c in FIG. 5;

FIG. 7 is a sectional view of a modified isolation structure of the embodiment in FIG. 6;

FIG. 8 is a sectional view of a light-emitting device with the light-emitting functional layer removed at position a in FIG. 1;

FIG. 9 is a flow diagram of a method for preparing a display panel according to an embodiment of the present application;

FIG. 10 is a sectional view of a light-emitting device with the light-emitting functional layer removed according to another embodiment of the present application;

FIG. 11 is an enlarged view of position d in FIG. 10.

### DETAILED DESCRIPTION OF THE EMBODIMENTS

To make the object, embodiments, and advantages of the present application more clear, the present application will be described in further detail below with reference to specific embodiments and accompanying drawings.

It should be noted that unless otherwise defined, the terms or scientific terms used in the embodiments of the present application should be understood in their ordinary meaning by persons in the field to which the present application belongs. The words “first,” “second,” and similar terms used in the embodiments of the present application do not indicate any order, quantity, or importance, but are merely used to distinguish different components. Words such as “include” or “include” mean that the elements or objects appearing before such words encompass the elements or objects listed after such words and their equivalents, without excluding other elements or objects. Words such as “connect” or “connected” are not limited to physical or mechanical connections, but may include electrical connections, whether direct or indirect.

Words such as “upper,” “lower,” “left,” “right” are only used to indicate relative positional relationships, and such relative positional relationships may change accordingly when the absolute position of the described object changes.

When fabricating the light-emitting layer of the display panel, an insulating layer is first formed on an array substrate, then a conductive layer is deposited on the insulating layer and patterned to prepare a first electrode (which serves as an anode), followed by depositing a pixel defining layer on the first electrode, and then forming an isolation structure and a light-emitting functional layer or forming an isolation structure, a light-emitting functional layer and an encapsulation layer on the pixel defining layer.

In further research on the process of the pixel defining layer, the applicant found that when the boundary of the first electrode has an undercut structure due to the patterning process, cracks/fissures easily occur in the single-layer pixel defining layer structure covering this area, which allows external moisture to easily penetrate into the pixel area through these cracks/fissures, leading to pixel failure.

Based on this, the present application provides a display panel, preparation method, and display device to solve the above problems. See the following embodiments for details.

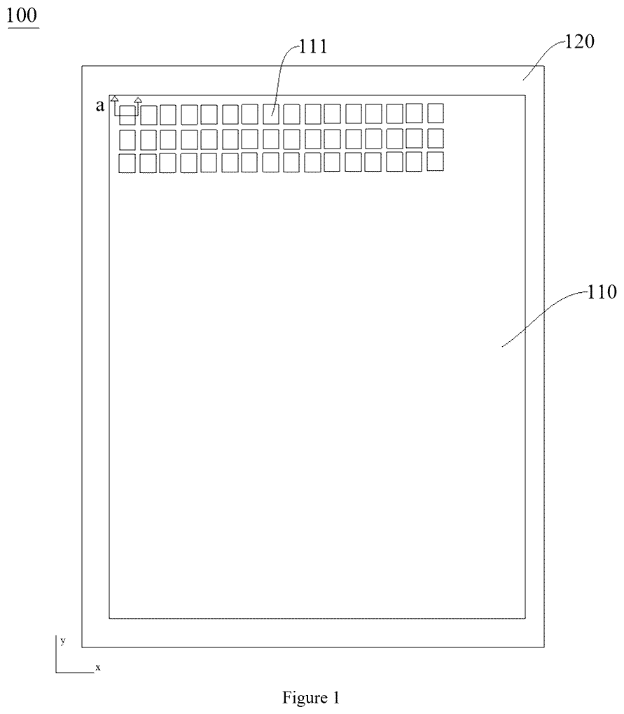

As shown in FIG. 1, it is a structural diagram of a display panel according to an embodiment of the present application.

The display panel 100 includes a display area 110 (also called AA area) and a non-display area 120 (also called border area/NA area) located outside the display area 110.

The display area 110 includes a plurality of light-emitting devices 111 arranged in a predetermined pattern, including first light-emitting devices, second light-emitting devices, and third light-emitting devices of different colors. The light-emitting devices are prepared by full-surface vapor deposition on the substrate combined with etching, which can further reduce the width of light-emitting devices and/or gaps between adjacent light-emitting pixels, to increase pixel density to greater than 400 PPI (such as 403 PPI, PPI also called Pixels Per Inch). This breaks through the current limitation of difficult further improvement in pixel density of OLED display panels, and avoids quality issues and high mask costs caused by factors such as repeated mesh fixing of masks and mask sagging in mask schemes. In this embodiment, the first light-emitting devices (blue light-emitting devices), second light-emitting devices (red light-emitting devices), and third light-emitting devices (green light-emitting devices) are prepared in sequence. In other embodiments, the preparation order is first light-emitting devices, third light-emitting devices, and second light-emitting devices, or there may be no restriction on the preparation order.

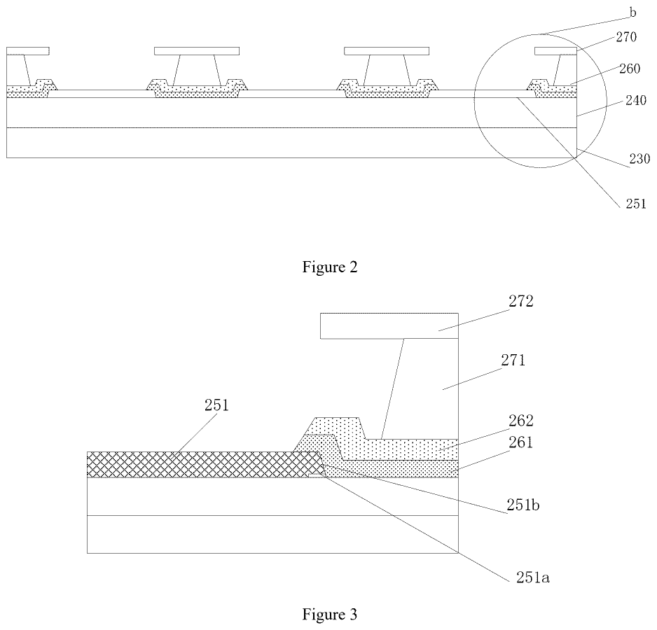

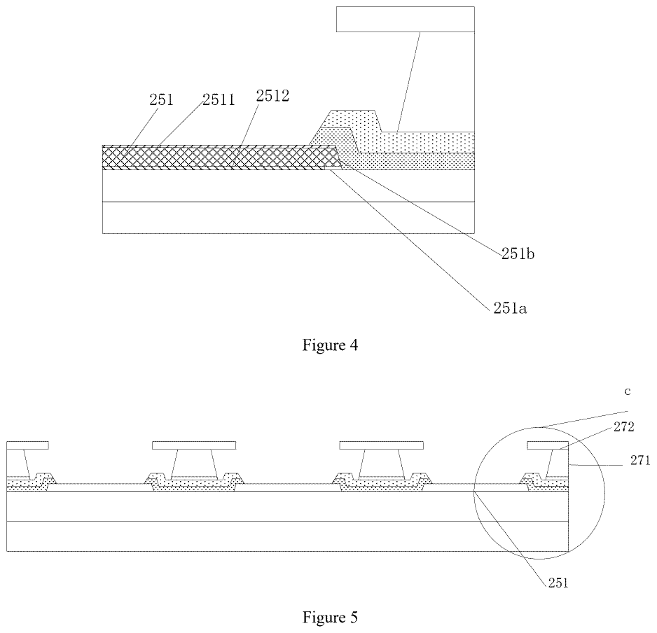

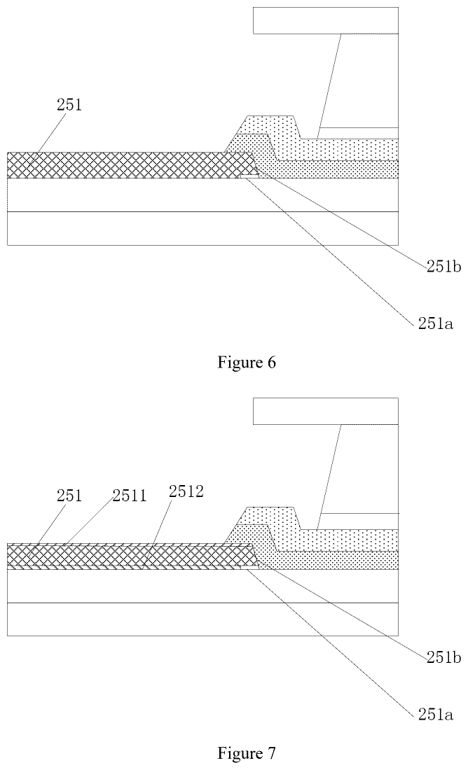

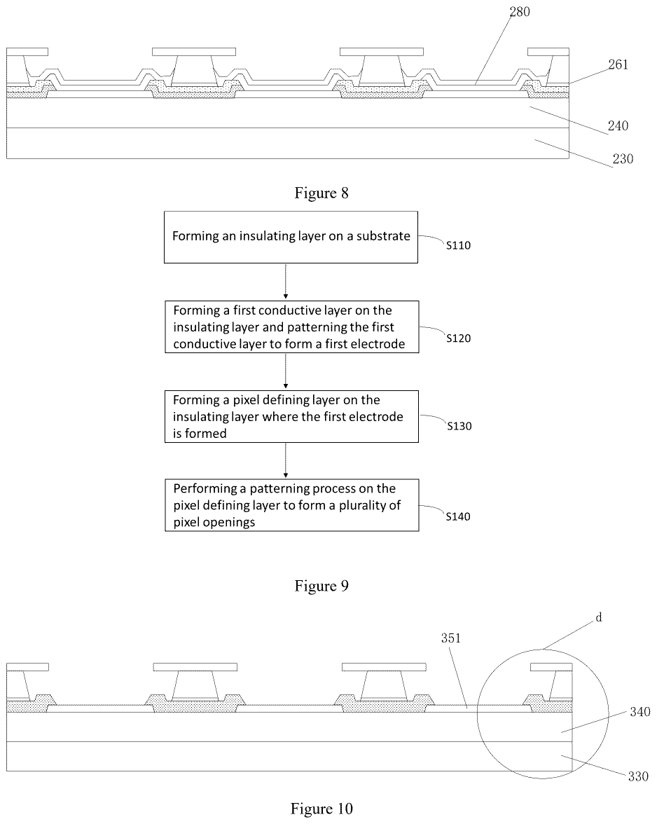

FIG. 2 shows a sectional view of position a in FIG. 1 (with the light-emitting functional layer and encapsulation layer omitted).

The display panel includes a substrate 230, an insulating layer 240, a plurality of first electrodes 251, and a pixel defining layer 260.

The substrate 230 is a flexible substrate made of materials such as polyimide (PI), polyethylene naphthalate (PEN), or polyethylene terephthalate (PET), or a mixture of these materials, or the substrate 230 is a rigid substrate made of glass material.

A driving layer is disposed on the substrate 230, covering both the display area and non-display area. The portion of the driving layer corresponding to the display area includes a plurality of pixel driving circuits, with the display functional layer disposed on this driving circuit layer. The pixel driving circuit may include a plurality of transistors (TFT), capacitors, etc., with topologies such as 7T1C circuit, 7T2C circuit, 8T1C circuit, or 8T2C circuit, without limitation, as long as it can drive the light-emitting device. The pixel driving circuit is correspondingly connected to the light-emitting device to control it on/off states and brightness. In one embodiment, the driving layer has a plurality of gate driving circuits (also called GIP/GOA circuit) corresponding to the non-display area, which are electrically connected to corresponding pixel driving circuits. The gate driving circuit is disposed on one side or two opposite sides of the display area. The driving layer has a bonding area (not shown) corresponding to the non-display area for mounting bonding components in subsequent processes.

The insulating layer 240 is disposed on the substrate 230, with the first electrode 251 disposed on the side of the insulating layer 240 away from the substrate 230. The insulating layer 240 covers the display area. In one embodiment, the insulating layer 240 covers both the display area and non-display area.

The pixel defining layer 260 is disposed on the insulating layer 240 (such as on the insulating layer 240 in the display area), defining a plurality of pixel openings. The pixel defining layer is constructed to cover gaps between adjacent first electrodes 251, with the pixel openings exposing portions of the first electrodes 251. The pixel defining layer forms a mesh pattern, with the first electrodes 251 exposed through the mesh.

The pixel defining layer 260 includes a stacked structure of a first sub-pixel defining layer 261 and a second sub-pixel defining layer 262. The first sub-pixel defining layer 261 is disposed on the insulating layer 240 and the first electrode 251, while the second sub-pixel defining layer 262 is stacked on the first sub-pixel defining layer 261. The first sub-pixel defining layer 261 covers the side surface 251b of the first electrode 251, and there exists a gap between the edge of the first electrode 251 near the insulating layer 240 and the insulating layer 240. This design improves the issue of cracks occurring in single-layer pixel defining layers when the side surface of the first electrode 251 has an undercut structure (where the side surface of the first electrode is not perpendicular to the plane of the substrate).

The materials of the first sub-pixel defining layer 261 and the second sub-pixel defining layer 262 are different. In one embodiment, the first sub-pixel defining layer 261 uses silicon nitride (SiN) or silicon oxide (SiO) or other inorganic materials not containing SiN or SiO, while the second sub-pixel defining layer 262 uses silicon oxide (SiO) or silicon nitride (SiN) or other inorganic materials not containing SiN or SiO. In one embodiment, since silicon oxide (SiO) has better etching resistance than silicon nitride (SiN), the second sub-pixel defining layer 262 uses silicon oxide (SiO) to provide better etching resistance for the surface of the pixel defining layer 260, thus preventing the impact of subsequent processes on the pixel defining layer 260. The first sub-pixel defining layer 261 uses silicon nitride (SiN) to improve coverage. The thickness of the first sub-pixel defining layer 261 is greater than or equal to the thickness of the second sub-pixel defining layer 262. In one embodiment, the ratio of the thickness of the first sub-pixel defining layer 261 to the second sub-pixel defining layer 262 is between 4:1 and 1.5:1. For example, the thickness of the first sub-pixel defining layer 261 is between 2000-4000 Å, while the thickness of the second sub-pixel defining layer 261 is between 500-2000 Å.

The first sub-pixel defining layer continuously covers the side surface 251b of the first electrode, and there exists an unfilled gap 251a beneath the first electrode that is not filled by the first sub-pixel defining layer 261. In one embodiment, the first sub-pixel defining layer 261 covers the insulating layer 240 and continuously extends from the side surface 251b of the first electrode to cover the surface of the first electrode 251 away from the substrate, and there exists an unfilled gap 251a near the first sub-pixel defining layer side of the first electrode 251.

In one embodiment, an oxygen content in the second sub-pixel defining layer is greater than an oxygen content in the first sub-pixel defining layer.

In one embodiment, when preparing the first sub-pixel defining layer, the lateral deposition rate of the first inorganic layer is increased to achieve rapid sealing at the undercut of the first electrode, to leave a partial gap 251a under the first electrode 251 (where no inorganic material is filled). Then, the second sub-pixel defining layer is prepared, thus avoiding (inorganic) cracks at the boundary (undercut structure) of the first electrode.

In one embodiment, ITO (Indium Tin Oxide) films are disposed on both upper and lower opposite sides of the first electrode. In one embodiment, the ITO film located at the edge of the first electrode 251 and near the insulating layer 240 has a gap near the lower side of the first electrode 251. The first sub-pixel defining layer 261 covers the insulating layer 240 and continuously extends from the side surface 251b of the first electrode 251 to cover the surface of the first electrode 251 away from the substrate 230, and the first sub-pixel defining layer 261 does not fill the gap. This gap is enclosed by the first electrode 251, the ITO film, the insulating layer 240, and the pixel defining layer 260.

In one embodiment, the display panel also includes an isolation structure 270.

The isolation structure 270 is disposed on the pixel defining layer 260, including a support portion 271 and a crown portion 272. The support portion 271 is located on the side of the pixel defining layer 260 away from the substrate 230, and the crown portion 272 is disposed on the side of the support portion 271 away from the pixel defining layer 260, defining a plurality of isolation openings that correspond to and communicate with the pixel defining openings. The width of the crown portion 272 is greater than the width of the support portion 271, meaning the orthogonal projection of the crown portion 272 on the substrate 230 covers the orthogonal projection of the support portion 271 on the substrate 230. The support portion 271 includes a first sub-support portion 271a (made of molybdenum or titanium nitride) disposed on the pixel defining layer 260, and a second sub-support portion 271b (made of aluminum) disposed on the first sub-support portion 271a. The isolation structure includes metallic materials such as molybdenum, aluminum, and titanium. Regarding the structure of the isolation structure (also called partition structure), related embodiments are recorded in patents (applications) CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072, CN116685174A, whose contents are incorporated herein by reference.

In one embodiment, the isolation structure is located on the substrate 230, with the pixel defining layer 260 between the isolation structure and the layer containing the first electrode 251.

In one embodiment, the display panel also includes a display functional layer 280 and an encapsulation layer.

The display functional layer includes a plurality of light-emitting devices, with each light-emitting device including a first electrode, a light-emitting functional layer, and a second electrode. The light-emitting functional layer is at least partially located within the pixel opening, and the second electrode is disposed on the light-emitting functional layer and contacts the support portion (the second electrode is electrically connected to the support portion). The first electrode is an anode, and the second electrode is a cathode. In some embodiments of this disclosure, certain film layers in the light-emitting functional layer, such as the light-emitting layer, is prepared using non-vapor deposition methods like inkjet printing. The specific method is selected based on the materials of these film layers. For example, when these film layers are made of polymer materials unsuitable for vapor deposition, inkjet printing is used. The encapsulation layer covers the second electrode and contacts the support portion.

Next, a method for preparing a display panel according to embodiments of the present application will be described.

The preparation method includes the following steps:

S110. Forming an insulating layer on a substrate, where the insulating layer can cover both the display area for light emission and the border area surrounding the display area. The substrate is either a flexible substrate (such as polyimide (PI)) or a rigid substrate (such as glass).

S120. Forming a first conductive layer on the insulating layer and patterning the first conductive layer to form a first electrode. This step includes forming the first conductive layer on the side of the insulating layer away from the substrate through deposition, sputtering, or vapor deposition, followed by etching to obtain the first electrode. The first electrode covers the display area.

S130. Forming a pixel defining layer on the insulating layer where the first electrode is formed. This step includes: first depositing a first sub-pixel defining layer, then depositing a second sub-pixel defining layer on the first sub-pixel defining layer, where the material of the second sub-pixel defining layer is different from the material of the first sub-pixel defining layer. The first and second sub-pixel defining layers combine to form the pixel defining layer, which continuously covers the insulating layer, the side surface of the first electrode, and a portion of the surface of the first electrode away from the insulating layer. This step also includes adjusting the deposition parameters of the pixel defining layer, such as adjusting the lateral deposition rate when depositing the pixel defining layer, to ensure rapid deposition of the first sub-pixel defining layer on the insulating layer and first electrode. This way, even when the first electrode boundary has an undercut structure (where the boundary is not perpendicular to the substrate plane), rapid sealing is achieved at the undercut during deposition. Additionally, the second sub-pixel defining layer is deposited on the side of the first sub-pixel defining layer away from the substrate at a slower rate than the first sub-pixel defining layer, to improve the pixel defining layer placement on the first electrode and avoid cracks at the undercut structure. The deposition rate of the first sub-pixel defining layer is greater than the deposition rate of the second sub-pixel defining layer. In one embodiment, the deposition rate of the first sub-pixel defining layer is less than or equal to 5000 Å/minute, while the deposition rate of the second sub-pixel defining layer is greater than or equal to 1000 Å/minute. In one embodiment, the deposition rate of the first sub-pixel defining layer is between 4000-5000 Å/minute, and the deposition rate of the second sub-pixel defining layer is between 1000-4000 Å/minute. Furthermore, the first sub-pixel defining layer uses silicon nitride (SiN), and the second sub-pixel defining layer uses silicon oxide (SiO).

S140. Performing a patterning process on the pixel defining layer to form a plurality of pixel openings. In this step, the first and second sub-pixel defining layers are patterned through a single etching process to form pixel openings that penetrate through both layers.

In other embodiments, the first sub-pixel defining layer is deposited and patterned first, followed by the deposition and patterning of the second sub-pixel defining layer, to obtain pixel openings that penetrate through both sub-pixel defining layers.

In one embodiment, before step S140, the method further includes:

Depositing an isolation functional layer on the pixel defining layer and performing a patterning process on the isolation functional layer to form an isolation structure, which defines a plurality of isolation openings.

In one embodiment, after step S140, the method further includes: preparing light-emitting devices, including:
Vapor depositing a light-emitting functional layer corresponding to the first electrode in the isolation opening;
Vapor depositing a second conductive material layer on the light-emitting functional layer to form a second electrode that is electrically connected to the isolation structure in each isolation opening;
Depositing an encapsulation layer (also called first encapsulation layer) on the second electrode by full-surface deposition. Then applying photoresist (PR) on the encapsulation layer and patterning applying photoresist to form a photoresist pattern. Using the photoresist pattern as a mask to etch the surface of the display panel, removing the encapsulation layer, second electrode, and light-emitting functional layer not covered by the photoresist pattern; then removing the remaining photoresist pattern to obtain the first light-emitting device, followed by preparing the second and third light-emitting devices using similar steps.

It should be noted that the display panel can also include other functional structures, such as a touch control structure for touch functionality. For example, the touch control structure is a touch panel or touch layer, where the touch panel is attached to the display panel through lamination, or the touch layer is directly prepared on the encapsulation layer of the display panel, facilitating a thin design of the display panel.

In the above embodiments, the pixel defining layer 260 refers to the layer whether it has pixel openings or not, without distinction in this document.

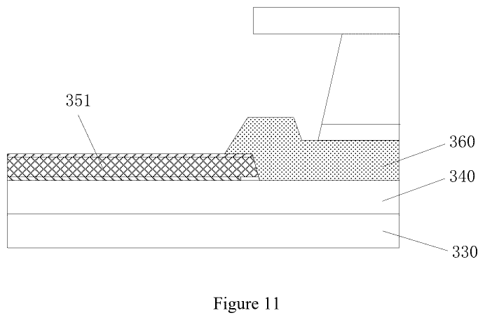

Furthermore, in another embodiment of the present application, as shown in FIGS. 10 and 11, the display panel includes a pixel defining layer 360 with only one film layer. Other than this, the remaining film layer structure of the display panel is the same as in the previous embodiment, so no further elaboration is needed. In one embodiment, the pixel defining layer 360 covers the edge of the first electrode 351, and there exists a gap at the edge of the first electrode 351 near the insulating layer 340, which is not filled by the pixel defining layer 360.

The thickness of the pixel defining layer 360 is between 2000-6000 Å, and the pixel defining layer 360 can use silicon nitride (SiN) or silicon oxide (SiO) or other inorganic materials not containing SiN or SiO. In one embodiment, the pixel defining layer 360 uses silicon oxide (SiO). When preparing this pixel defining layer 360, inorganic materials are rapidly deposited first to quickly seal the undercut structure at the boundary of the first electrode 351, followed by reducing the lateral deposition rate of inorganic materials for normal deposition, that is: as deposition time increases, reduce the lateral deposition rate of inorganic materials to form the pixel defining layer, and then perform patterning process to form pixel openings. In one embodiment, the initial lateral deposition rate of the first pixel defining layer is 4000-5000 Å/minute, with the subsequent lateral deposition rate reduced to 1000-4000 Å/minute.

The present application provides a display device including the display panel from the above embodiments. The pixel density range of this display device reaches 400PPI to 7000PPI, suitable for scenarios such as televisions, laptops, etc., and can also be applied to micro-display products (such as AR, VR, etc.). Furthermore, the display device is any product or component with display functionality, such as televisions, digital cameras, mobile phones, watches, tablets, laptops, navigation devices, consoles, etc.

Although the present application has been described in conjunction with specific embodiments, based on the foregoing description, many substitutions, modifications, and variations will be apparent to those in the art.

It should be noted that some embodiments of the present application have been described above. Other embodiments are within the appended claims. In some cases, the actions or steps recited in the claims may be performed in a different order than that described in the above embodiments and still achieve the desired results. Additionally, the processes depicted in the drawings do not necessarily require the specific order or sequential order shown to achieve the desired results. In some embodiments, multitasking and parallel processing may be possible or advantageous.

The embodiments of the present application are intended to cover all such substitutions, modifications, and variations that fall within the broad appended claims. Therefore, any omission, modification, equivalent substitution, improvement, etc., made within the and principles of the embodiments of the present application should be included within the protection of the present application.

1. A display panel, comprising:
a substrate;
an insulating layer disposed on the substrate, wherein a plurality of first electrodes are spaced apart from each other on a side of the insulating layer away from the substrate; and
a pixel defining layer disposed on the side of the insulating layer away from the substrate and having a plurality of pixel openings, wherein an orthogonal projection of a pixel opening on the substrate in a thickness direction of the substrate overlaps with a portion of the first electrode and covers an edge of the first electrode, and a gap exists between the edge of the first electrode and the insulating layer.

2. The display panel according to claim 1, wherein
the pixel defining layer continuously covers the insulating layer, a side surface of the edge of the first electrode, and a portion of a surface of the first electrode away from the substrate, and the gap is enclosed by the first electrode, the insulating layer, and the pixel defining layer.

3. The display panel according to claim 2, wherein the pixel defining layer comprises:
a first sub-pixel defining layer and a second sub-pixel defining layer, wherein the second sub-pixel defining layer is disposed on the first sub-pixel defining layer, and a thickness of the first sub-pixel defining layer is greater than or equal to a thickness of the second sub-pixel defining layer.

4. The display panel according to claim 3, wherein a ratio of the thickness of the first sub-pixel defining layer to the thickness of the second sub-pixel defining layer is between 4:1 and 1.5:1.

5. The display panel according to claim 3, wherein
a material of the first sub-pixel defining layer is different from a material of the second sub-pixel defining layer.

6. The display panel according to claim 5, wherein an oxygen content in the second sub-pixel defining layer is greater than an oxygen content in the first sub-pixel defining layer.

7. The display panel according to claim 1, wherein ITO films cover both upper and lower opposite sides of the first electrode.

8. The display panel according to claim 7, wherein the ITO film located at the edge of the first electrode and closed to the insulating layer has a gap, the pixel defining layer covers the insulating layer and continuously extends from the side surface of the first electrode to cover a portion of the surface of the first electrode away from the substrate, and the gap is enclosed by the first electrode, the ITO film, the insulating layer, and the pixel defining layer.

9. The display panel according to claim 1, further comprising:
an isolation structure disposed on the pixel defining layer, wherein the isolation structure defines a plurality of isolation openings corresponding to the plurality of pixel openings, and the isolation structure comprises a support portion and a crown portion, wherein the support portion is disposed on the pixel defining layer, and the crown portion is disposed on a side of the support portion away from the pixel defining layer and extends outward relative to the support portion.

10. The display panel according to claim 9, wherein the support portion comprises a first sub-support portion and a second sub-support portion, wherein the first sub-support portion is disposed on a side of the pixel defining layer away from the substrate, and the second sub-support portion is disposed on the first sub-support portion.

11. The display panel according to claim 10, further comprising:
a display functional layer comprising a plurality of light-emitting devices, wherein the light-emitting devices are correspondingly disposed in the isolation openings, and each light-emitting device comprises the first electrode, a light-emitting functional layer and a second electrode,
wherein the light-emitting functional layer is at least partially located in the pixel opening,
wherein the second electrode is disposed on the light-emitting functional layer and contacts the support portion.

12. The display panel according to claim 11, further comprising:
an encapsulation layer covering the second electrode and contacting the support portion.

13. The display panel according to claim 1, wherein
a driving layer is disposed on the substrate, the driving layer covers the display area and the non-display area,
the portion of the driving layer corresponding to the display area comprises a plurality of pixel driving circuits, and the display functional layer is disposed on the driving circuit layer.

14. A method for preparing a display panel, comprising:
forming an insulating layer on a substrate;
forming a first conductive layer on the insulating layer and patterning the first conductive layer to form a first electrode; and
forming a pixel defining layer having a plurality of pixel openings through a patterning process on the insulating layer where the first electrode is formed, wherein the pixel defining layer continuously covers the insulating layer, a side surface of the first electrode, and a portion of a surface of the first electrode away from the insulating layer.

15. The method for preparing the display panel according to claim 14, wherein the step of forming the pixel defining layer on the insulating layer where the first electrode is formed comprises:
adjusting a deposition rate of the pixel defining layer to make the pixel defining layer continuously cover the side surface of the first electrode.

16. The method for preparing the display panel according to claim 15, wherein the step of adjusting the deposition rate comprises: reducing the deposition rate of the pixel defining layer as deposition time increases.

17. The method for preparing the display panel according to claim 16, wherein the pixel defining layer comprises a first sub-pixel defining layer and a second sub-pixel defining layer, and before performing the patterning process on the pixel defining layer, the method comprises:
depositing the first sub-pixel defining layer first, then depositing the second sub-pixel defining layer on the first sub-pixel defining layer, wherein a material of the second sub-pixel defining layer is different from a material of the first sub-pixel defining layer; and
performing a patterning process on the second sub-pixel defining layer, wherein the first sub-pixel defining layer and the second sub-pixel defining layer jointly define the pixel opening.

18. The method for preparing the display panel according to claim 17, wherein a deposition rate of the first sub-pixel defining layer is greater than a deposition rate of the second sub-pixel defining layer, and a thickness of the first sub-pixel defining layer is greater than or equal to a thickness of the second sub-pixel defining layer.

19. The method for preparing the display panel according to claim 14, wherein before performing the patterning process on the pixel defining layer, the method further comprises:
depositing an isolation functional layer on the pixel defining layer, and performing a patterning process on the isolation functional layer to form an isolation structure, wherein the isolation structure defines a plurality of isolation openings.

20. A display device, comprising:
a display panel, comprising:
a substrate;
an insulating layer disposed on the substrate, wherein a plurality of first electrodes are spaced apart from each other on a side of the insulating layer away from the substrate; and
a pixel defining layer disposed on the side of the insulating layer away from the substrate and having a plurality of pixel openings, wherein an orthogonal projection of a pixel opening on the substrate in a thickness direction of the substrate overlaps with a portion of the first electrode and covers an edge of the first electrode, and a gap exists between the edge of the first electrode and the insulating layer.
